(19) United States
(12) Patent Application Publication
(10) Pub. No.: US 2007/0277959 A1
(43) Pub. Date: Dec. 6, 2007

(54) Heat dissipating device

(75) Inventor: Steven Shan, Taipei Hsien (TW)

Correspondence Address: BRUCE H. TROXELL, SUITE 1404, 5205 LEESBURG PIKE, FALLS CHURCH, VA, 22041, US

(73) Assignee: SI JING HARNG CO., LTD.

(21) Appl. No.: 11/445,328

(22) Filed: Jun. 2, 2006

(51) Int. Cl. H05K 7/20

(52) U.S. Cl. 165/80.3; 165/185; 361/704; 257/722

(57) ABSTRACT

A heat dissipating device for use with a heat-producing element in an electronic product includes a flat-plate heat collector and a plurality of parallelly arranged fins, both of which are made of a copper material to provide excellent heat conductivity. The fins are fixedly connected to one surface of the heat collector using a bonding agent, which is a molten state alloy containing copper, silver, and tin, and also provides excellent heat conductivity after becoming set. Heat produced by the heat-producing element during operation thereof is collected by the heat collector and transferred to the fins, and then carried away by air through heat exchange between the fins and the ambient air. The heat dissipating device employs the natural law of air convection to dissipate heat without consuming power or using other power-driven device.

### FIELD OF THE INVENTION

The present invention relates to a heat dissipating device, and more particularly to a heat dissipating device for use with a heat-producing element in an electronic product.

### BACKGROUND OF THE INVENTION

With the highly developed electronic technologies, all kinds of high-tech electronic products are constantly improved to provide diversified functions. The electronic products all include some elements that produce heat during operation thereof. These heat-producing elements include, for example, the power transistor in a power supply, the central processing unit (CPU) in the computer host, etc., and play an important role in determining the quality and service life of the electronic products. If the heat produced by these heat-producing elements during operation thereof is not properly removed, the accumulated heat would inevitably adversely affect the performance of the electronic products, and shorten the usable life of the heat-producing elements and of the electronic products.

The ways most frequently adopted by electronic product manufacturers to solve the problem of heat dissipation include increasing the heat dissipating area by mounting, for example, aluminum extrusion radiating fins, and speeding the air convection in the electronic products by, for example, mounting additional cooling fans.

With the advancements in the industrial field, various types of electronic products are designed to have further reduced dimensions, higher power, and faster operation speed. The higher power and faster operation speed of the electronic products also results in high amount of heat produced during the operation of the products. For example, when the CPU of a computer processes data at an increased speed, it consumes more power to causes largely raised temperature thereof. Meanwhile, the CPU has a largely reduced volume with the advanced production technique therefor, and the computer host also has a correspondingly reduced volume. The high amount of heat produced by the CPU during the high-speed operation thereof tends to quickly accumulate in the relatively small inner space of the computer host to cause the problem of heat dissipation.

A typical solution to the heat accumulated in the computer host is to mount radiating fins on the CPU. One or more cooling fans are required to mount on the computer case when the temperature of the CPU could not be successfully lowered to a target level, so as to improve the air convection in the computer case to quicken the dissipation of heat produced by the CPU. The CPU normally has a service life much longer than that of a general cooling fan. Therefore, the cooling fan usually becomes failed earlier than the CPU. When the cooling fan is failed, the temperature of CPU would constantly increase to result in a down computer or a damaged CPU due to an exceeded temperature thereof. In the case of a power supply, a failed cooling fan would result in a burned-out power transistor or the activation of a protective circuit to shut down the power supply.

To enhance the performance of the heat dissipating device and to ensure the normal operation of the CPU, some manufacturers try to install a backup cooling fan in the computer host, so that the backup cooling fan automatically starts operating when the original cooling fan is failed, protecting the computer from shut down or the CPU from damage due to an exceeded temperature of the CPU. Taiwanese Patent No. 90215320 discloses a heat dissipating device for computer CPU, in which such backup cooling fan is included. There are also other manufacturers adopt a heat dissipating device using a liquid coolant. In this case, a complicate coolant pipeline and pump system must be designed to circulate the liquid coolant. Taiwanese Patent No. 92203235 entitled “Liquid Cooling Device for CPU” discloses such heat dissipating device using a liquid coolant.

To avoid the heat-producing element in the electronic product from damage and resulting in a down product due to a cooling fan having a service life shorter than that of the heat-producing element, it is therefore tried by the inventor to develop a heat dissipating device that enables quick heat dissipation without the need of using any cooling fan, so as to prolong the usable life of the electronic product and facilitate the reduction of product dimensions.

### SUMMARY OF THE INVENTION

A primary object of the present invention is to provide a heat dissipating device for use with a heat-producing element in an electronic product, so that heat produced by the heat-producing element during operation thereof could be quickly carried away by air to lower the temperature of the heat-producing element, allowing the heat-producing element to work under a safety temperature.

The heat dissipating device of the present invention employs the physical principles of heat conduction and air convection to dissipate heat without the need of using other power-driven means. Therefore, the heat dissipating device may be used with the electronic product without changing the circuit design of the electronic product.

The heat dissipating device according to the present invention includes a flat-plate heat collector having one surface associated with the heat-producing element, and a plurality of fins fixedly arranged on another surface of the heat collector opposite to the heat-producing element. The heat collector and the fins all are made of a metal material with high heat conductivity, so that heat produced by the heat-producing element during operation thereof could be quickly transferred to the heat collector and dissipated into air via the fins. In this way, the temperature of the heat-producing element could be quickly lowered to achieve the purpose of heat dissipation.

In the present invention, the fins are bonded to the surface of the flat-plate heat collector using a bonding agent, which is a molten state alloy and provides excellent heat conductivity when becoming set.

In the present invention, the fins may be further coated on outer surfaces with copper powder having excellent heat conductivity, so as to increase a surface area of the fins to enhance the heat dissipating effect thereof.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is a perspective view of a heat dissipating device according to an embodiment of the present invention;

FIG. 2 is a front view of the heat dissipating device of FIG. 1;

FIG. 3 is an enlarged view of the circled area of FIG. 2; and

FIG. 4 is a fragmentary enlarged perspective view of a fin included in the heat dissipating device of the present invention.

### DETAILED DESCRIPTION OF THE PREFERRED EMBODIMENTS

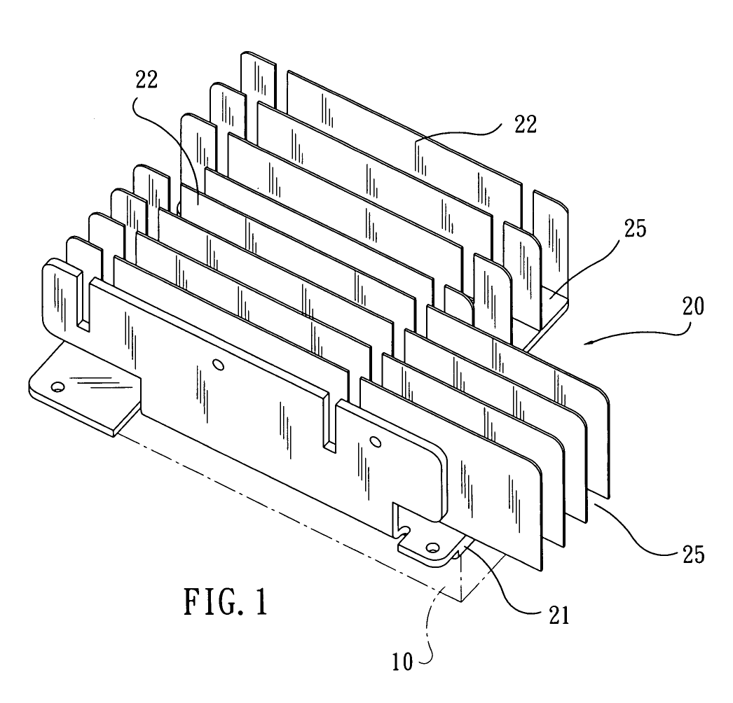

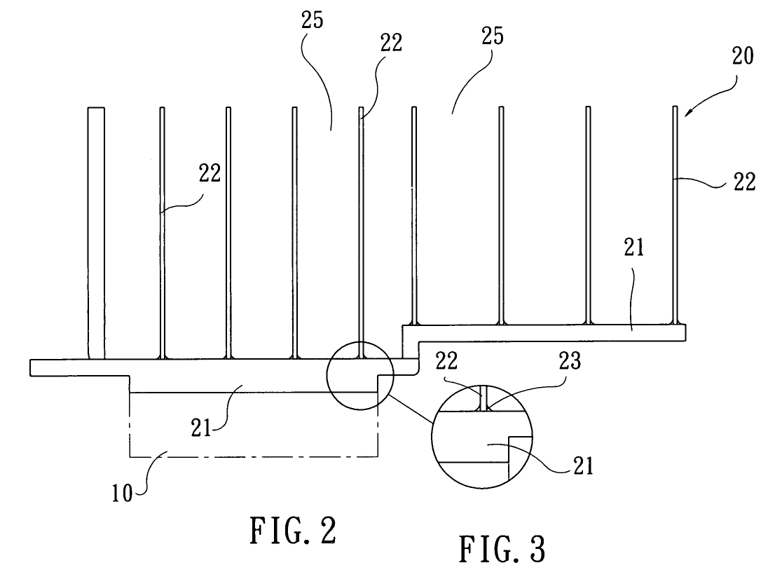

Please refer to FIGS. 1 and 2 that are perspective and front views, respectively, of a heat dissipating device 20 according to an embodiment of the present invention. As shown, the heat dissipating device 20 includes a flat-plate heat collector 21 having one surface associated with a heat-producing element 10, which may be, for example, a central processing unit (CPU) on a circuit board, and a plurality of fins 22 associated with another surface of the flat-plate heat collector 21 opposite to the heat-producing element 10. As can be clearly seen from FIG. 3, which is an enlarged view of the circled area of FIG. 2, the fins 22 are parallelly fixedly bonded to the surface of the heat collector 21 using a bonding agent 23 to define an air passage 25 between any two adjacent fins 22 for air convection. The bonding agent 23 is an alloy material in molten state. When the bonding agent 23 is set, it provides excellent heat conductivity. The heat collector 21 and the fins 22 all are made of a material with excellent heat conductivity. And, copper is one of the preferred materials for the heat collector 21 and the fins 22.

The high amount of heat produced by the heat-producing element 10 during operation thereof is collected by the flat-plate heat collector 21 and transferred to the fins 22, and then dissipated into air through heat exchange between the heated fins 22 and the ambient air. Since the fins 22 and the flat-plate heat collector 21 are bonded together to form an integral body, heat collected by the heat collector 21 may be quickly transferred to the fins 22. Hot air produced in the heat exchange between the air and the fins 22 would flow upward while cold ambient air flows into the air passages 25 at two lateral ends of the fins 22, enabling continuous heat exchange between the air and the flat-plate heat collector 21 and the fins 22. The heat exchange between the fins 22 and the air is a natural law. The heat-producing element 10 may keep working at a safety temperature so long as the heat produced by the heat-producing element 10 is quickly carried away by the heat dissipating device 20.

The bonding agent 23 used to bond the fins 22 to the heat collector 21 is a molten alloy containing copper, silver, and tin. Wherein copper and silver act to increase the heat conductivity of the bonding agent 23. When the fins 22 and the heat collector 21 are made of copper, the copper contained in the bonding agent 23 causes an extremely solid bonding of the fins 22 to the heat collector 21. The tin gives the bonding agent 23 an improved bonding ability. With the molten alloy of copper, silver and tin, the bonding agent 23 would not adversely reduce the heat conductivity of the heat dissipating device 20, so that the heat collected by the flat-plate heat collector 21 could be successfully transferred to the fins 22.

Generally, heat produced by the heat-producing element 10 in an electronic product is dissipated through heat exchange between the heat collector 21 and the fins 22 and the ambient air, so as to lower the temperature of the heat-producing element 10. The heat dissipating device 20 of the present invention takes advantage of the natural law of air convection, and all the low-temperature air inside the electronic product could be utilized in performing the heat exchange in the heat dissipating device 20, so that the temperature inside the electronic product is uniformly lowered to allow the heat-producing element 10 to have a temperature lower than the safety temperature.

The heat dissipating device 20 of the present invention is made of copper material, which has excellent heat conductivity to enable quick transfer of heat. The fins 22 provided in the heat dissipating device 20 are not specifically limited in number. However, the fins 22 must be sufficiently spaced from each other to allow air convection in the air passages 25, so that heat transferred from the heat collector 21 to the fins 22 could be quickly carried away by air to achieve the purpose of quick heat dissipation.

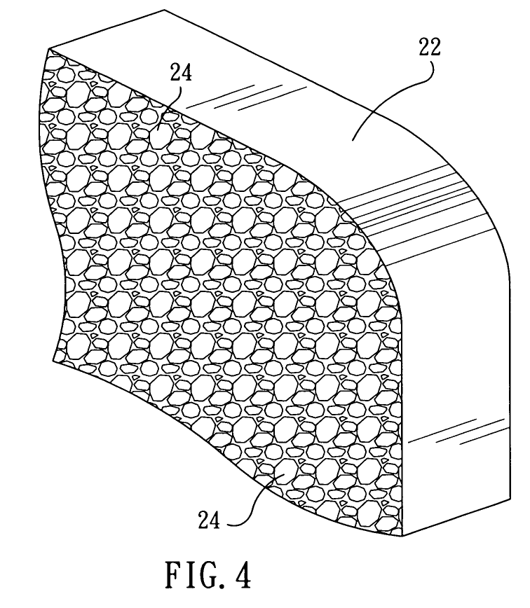

Please refer to FIG. 4 that is a fragmentary enlarged perspective view of the fin 22. As shown, copper powder 24 is coated on each fin 22 to produce relatively coarse outer surfaces on the fin 22, so as to increase the surface area of the fin 22, and accordingly, the area of the fin 22 for heat exchange. In this manner, heat could be dissipated into air more quickly. The copper powder 24 is fixedly coated on the fins 22 via the molten bonding agent 23 that containing copper, silver, and tin.

The copper material has a heat conductivity of 0.922, and is the best heat transfer substance next to silver. The present invention is designed based on the principle of quickly dissipating the heat into air, and causing the dissipated heat to uniformly distribute in the whole available space through air convection, so that the temperature of the heat-producing element 10 may be effectively and efficiently lowered.

The heat-producing element 10 may be a CPU of a computer, or a power transistor of a power supply. In the present invention, the flat-plate heat collector 21 may also be used to collect heat produced by two or more heat-producing elements 10. The collected heat is then transferred to the fins 22 and dissipated into air.

The present invention is therefore a very simple but highly efficient heat dissipating device 20.

The present invention has been described with a preferred embodiment thereof and it is understood that many changes and modifications in the described embodiment can be carried out without departing from the scope and the spirit of the invention that is intended to be limited only by the appended claims.

What is claimed is:

1. A heat dissipating device for use with a heat-producing element in an electronic product, comprising:
a flat-plate heat collector having one surface associated with said heat-producing element; and
a plurality of fins bonded via a bonding agent to another surface of said flat-plate heat collector opposite to said heat-producing element; and said fins being parallelly arranged to define an air passage between any two adjacent fins for air convection.

2. The heat dissipating device as claimed in claim 1, wherein said flat-plate heat collector and said fins are made of copper material.

3. The heat dissipating device as claimed in claim 1, wherein said bonding agent is a molten state alloy containing copper and tin.

4. The heat dissipating device as claimed in claim 1, wherein said bonding agent is a molten state alloy containing copper, silver, and tin.

5. The heat dissipating device as claimed in claim 1, wherein said fins are coated on outer surfaces with copper powder, and said copper powder is coated on said fins via a bonding agent.

6. The heat dissipating device as claimed in claim 5, wherein said bonding agent is a molten state alloy containing copper and tin.

7. The heat dissipating device as claimed in claim 5, wherein said bonding agent is a molten state alloy containing copper, silver, and tin.

8. The heat dissipating device as claimed in claim 1, wherein said heat-producing element is a central processing unit of a computer.

9. The heat dissipating device as claimed in claim 1, wherein said heat-producing element is a power transistor of a power supply.
